(19) United States
(12) Patent Application Publication
(10) Pub. No.: US 2005/0070125 A1
(43) Pub. Date: Mar. 31, 2005

(54) Photo resist dispensing system and method

(76) Inventor: Leon A. Leonard, Orlando, FL (US)

Correspondence Address: AGERE SYSTEMS INC., FOUR CONNELL DRIVE, BERKELEY HEIGHTS, NJ, 07922-2747, US

(21) Appl. No.: 10/674,757

(22) Filed: Sep. 30, 2003

(51) Int. Cl. H01L 21/31

(52) U.S. Cl. 438/782

(57) ABSTRACT

A system and method for preventing coagulation of photo resist chemical in a photo resist coater. The system includes a valve assembly in fluid communication with at least two fluid flow lines and a dispensing nozzle. One flow line provides photo resist and one flow line provides solvent. In a related method, a valve assembly is controllable to send solvent through the nozzle to reduce coagulation of photo resist in or about the nozzle.

### FIELD OF THE INVENTION

The present invention relates to equipment used in the manufacture of semiconductor wafers in general, and more specifically, to systems and methods for dispensing photo resist.

### BACKGROUND OF THE INVENTION

Commonly, in semiconductor manufacturing, photo resist coaters dispense a thin layer of liquid photo resist on to a spinning silicon wafer as a step in the photolithographic process. The chemical properties of the photo resist change with exposure to light and this property is utilized to create a mask during various steps in the sequence of building circuit patterns on the semiconductor wafer.

The photo resist coater will typically include a dispensing nozzle or tube portion that receives photo resist from a flow line and dispenses the photo resist through a nozzle tip on to the wafer at a controlled rate. The flow line carrying the photo resist to the nozzle is connected to a reservoir containing photo resist. A pumping system transfers the photo resist through the flow line to the nozzle as needed. Coaters often include multiple photo resist dispensing nozzles which can each be connected to different reservoirs through separate flow lines. Such configurations make different types of photo resist or other chemicals readily available during the wafer manufacturing process.

Typically, the photo resist coater includes a dispense system controller or main controller which receives the specific details of the photo resist dispensing operations and carries out the operations of the photo resist coater tool. A secondary controller, called the pump controller, is typically configured to control the pumping system in communication with the main controller. During a production photo resist dispensing operation, the nozzle is typically positioned over a spinning wafer in a production position. For example, the wafer may be positioned on a rotatable plate, sometimes referred to as a coater plate. As photo resist is applied, the nozzle may oscillate back and forth from a central position above the wafer to a position near the edge to uniformly coat the wafer.

After a photo resist dispensing operation, some photo resist will typically remain in the tip of the nozzle and be exposed to air causing it to thicken and dry. If left unattended, this residual photo resist thickens and creates clumps in the tip of the nozzle. Such effects are referred to herein as coagulation. During a subsequent photo resist dispense operation, such coagulation can result in the formation of debris on the semiconductor wafer, creating defects which result in electrical failures of the semiconductor circuits.

Other types of chemicals used in the photo coat process include solvents whose function is to remove a thicker-layer of photo resist, sometimes referred to as an edge-bead, which builds up at the edge of a wafer during the photo coating process. Solvents are often paired with specific types of photo resist. One such solvent, Propylene Glycol Monomethyl Ether Acetate, or PGMEA, is typically paired with the Shipley AR3™ type photo resist. During edge bead removal, the PGMEA solvent is transferred from a reservoir and through a separate flow line and nozzle to the very edge of the wafer or to the underside of the wafer near the edge to remove unwanted photo resist. Other solvents used in the photo coat process, which may be used with other types of photo resist, include N-butyl Acetate, Acetone, Cyclohexnone, Ethyl Lactate, N-Methylpyrrolidone (NMP) (1-methyl, 2-Pyrrolidone), Tetrahydrofuran (THF), Propylene Glycol Monomethyl Ether (PGME), and Methyl amyl keytone (MAK.)

When the photo resist dispense nozzle has completed a production photo resist dispensing operation, the nozzle is rotated to an idle position. The nozzle stays in the idle position, filled with photo resist, until the next wafer lot is available. To mitigate coagulation while in this idle position, the nozzle is situated above a solvent cup containing solvent, such as PGMEA. The nozzle does not come into contact with liquid solvent in the cup, but rather, receives solvent vapors from the cup. Interaction of solvent vapors with the photo resist delays photo resist coagulation in the tip of the nozzle. This reduces, but does not eliminate, clogging of the nozzle.

To further reduce photo resist coagulation in the tip of the dispensing nozzle, a “dummy dispense” operation may be performed. That is, while the dispensing nozzle is in the idle position, the photo resist pump is periodically activated to apply fresh photo resist to the nozzle and the nozzle tip. During a dummy dispense operation, photo resist is pumped though the nozzle and into the solvent cup. The dummy dispense procedure may be repeated periodically while the nozzle is in the idle position. A drain in the solvent cup prevents overfilling of the cup and permits flushing of photo resist with solvent and replenishing the cup with the solvent.

It is now recognized that a more economical and effective procedure may be had to address problems relating to coagulation of photo resist in the nozzle tip.

### SUMMARY OF THE INVENTION

The afore-described procedures are, at best, wasteful resulting in substantial loss of expensive chemicals. The present invention provides a solution for avoiding coagulation of photo resist in manufacturing equipment.

In one form of the invention, a method is provided for manufacturing microelectronic devices. According to one embodiment, the method includes providing a photo resist coater tool having a coater plate and a nozzle connected to a fluid flow line. The nozzle is positionable over the coater plate. A valve assembly is positioned in the flow line to control flow between at least two fluid inputs and the nozzle. A wafer is positioned on the coater plate and the valve assembly is operated to dispense photo resist from the first of the fluid inputs and through the nozzle onto the wafer. The valve assembly stops the flow of photo resist and the nozzle is positioned over a solvent drain. The valve assembly then sends a solvent from a second of the fluid inputs through the flow line and nozzle to reduce coagulation of the photo resist in or about the nozzle.

In another form of the invention, a system is provided for dispensing photo resist which includes a nozzle configured to alternately receive photo resist for delivery on to a plurality of wafers or liquid solvent to prevent coagulation of photo resist in the nozzle when the nozzle is idle. In an example embodiment, at least two flow lines provide fluid communication to a valve positioned between the flow lines and the nozzle. One of the flow lines receives fluid from a photo resist source and the second flow line receives fluid from a solvent source. The valve is configured to select the movement of fluid from one or another of the flow lines and thereby enables movement of solvent through the nozzle to flush photo resist from the nozzle.

### DISCRIPTION OF THE FIGURES

FIG. 1 is a side elevation view in schematic form of a photo resist dispensing system according to the invention;

FIG. 2 is a partial schematic view from above of the photo resist dispensing system of FIG. 1; and

FIG. 3 is an exemplary flow control diagram for use in conjunction with the invention.

### DETAILED DESCRIPTION OF THE INVENTION

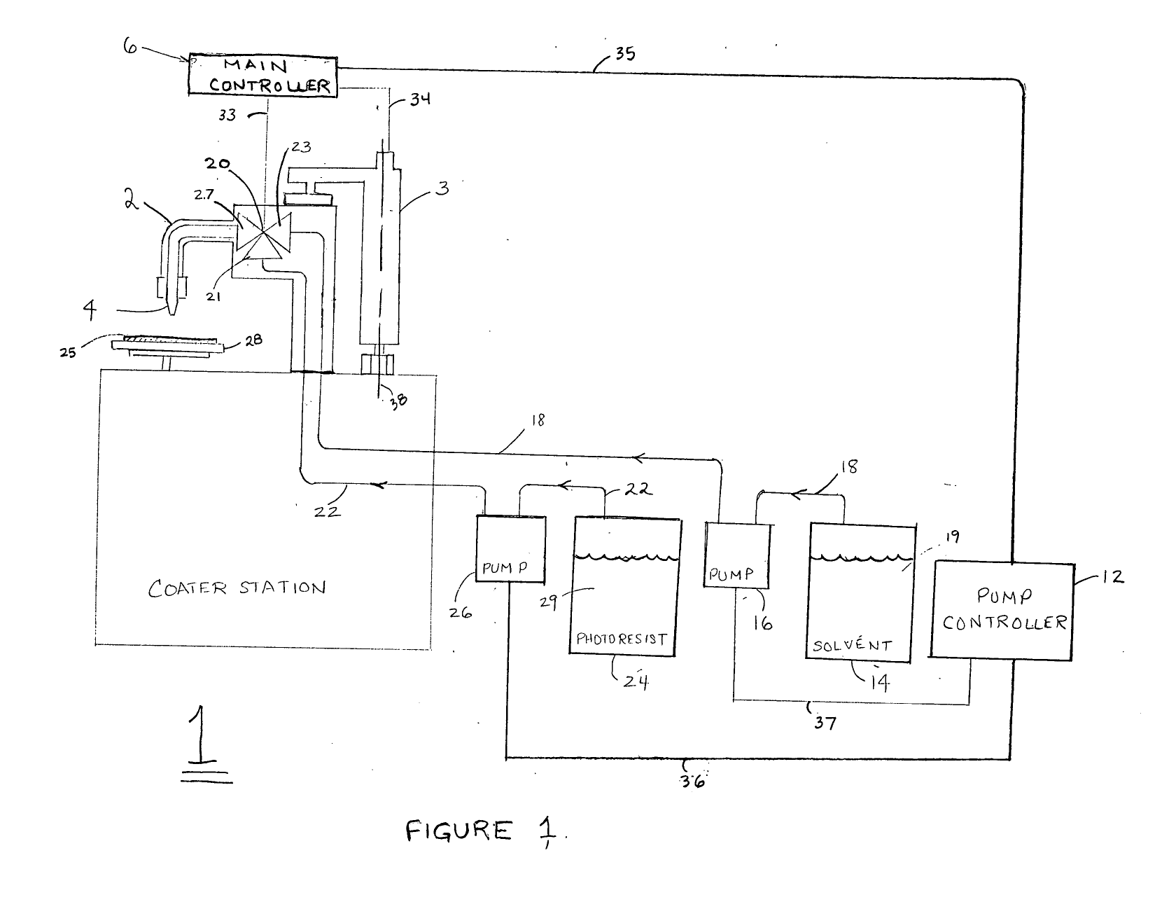

With reference to the figures generally, exemplary embodiments of a method and a photo resist coater tool system 1 for photo resist dispensing according to the invention are now described. As shown in FIG. 1, the photo resist coater tool system 1 includes a movable dispensing nozzle 2 having a nozzle tip 4 for dispensing fluid. Movement of the dispensing nozzle 2 is effected by a nozzle positioning mechanism 3. The system may be configured to have multiple nozzles such as nozzle 2. For simplicity, only one such nozzle 2 is shown while it is to be understood that the principles of this invention may be applied to multiple nozzles in photo resist coater tools.

A switching mechanism, such as a valve 20, is positioned to selectively control flow of fluid through dispensing nozzle 2 to the nozzle tip 4. The valve 20 is conventional and may be of the electronic, electromagnetic, pneumatic or hydraulic type and is shown as a three-way valve. A first input port 21 of the valve 20 is connected to a photo resist flow line 22 which can send photo resist 29 to the dispensing nozzle 2 from a photo resist source 24. An in-line photo resist pump 26 facilitates the transfer of photo resist. A second input port 23 to the valve 20 is connected to a solvent flow line 18 along which solvent 19 is sent to the dispensing nozzle 2 from a solvent source 14 via an in-line solvent pump 16. An output port 27 of the valve 20 is connected to the dispensing nozzle 2 to selectively dispense photo resist 29 or solvent 19 through the nozzle tip 4 depending on which of the input ports 21, 23 the valve 20 is configured to receive fluid from. A main controller 6 is configured to effect the movement of the dispensing nozzle 2 through communication with the nozzle positioning mechanism 3 and to control the input of fluid through one of the input ports 21, 23 of the valve 20. The main controller 6 also controls the activation of the solvent pump 16 and the photo resist pump 24 through communication with the pump controller 12. A valve control line 33 indicates communication from the main controller 6 to the valve 20, while a positioning control line 34 indicates communication from the main controller 6 to the nozzle positioning mechanism 3. A pump control line 35 indicates communication from the main controller 6 to the pump controller 12. Photo resist pump control line 36 and solvent pump control line 37 indicate communication between photo resist pump 26 and the solvent pump 16 to the pump controller 12.

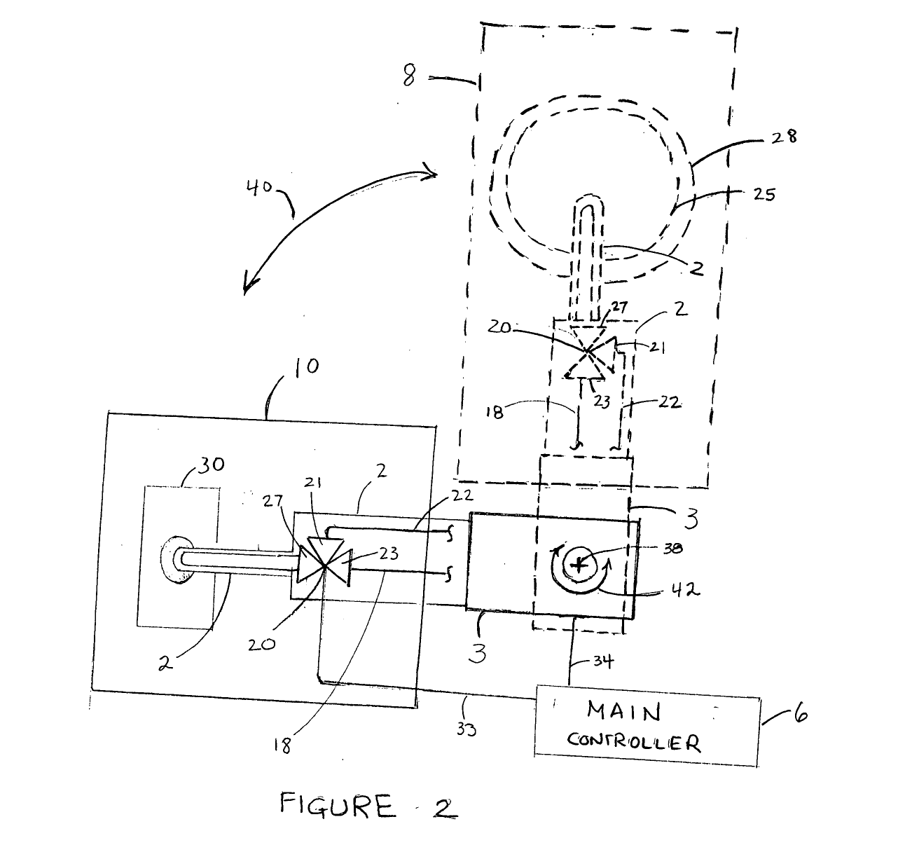

Referring next to the schematic view of FIG. 2, alternate positions of the dispensing nozzle 2 are illustrated. The dispensing nozzle 2 will typically be in a production position 8 (illustrated with phantom lines) for dispensing photo resist 29 on to a semiconductor wafer 25 positioned on a coater plate 28. When the production photo resist dispensing process is complete, the dispensing nozzle 2 is rotated to an idle position 10 over a solvent drain 30. Dispensing nozzle rotation is effected about axis 38 by the nozzle positioning mechanism 3 as illustrated by the arrows numbered 40 and 42.

Again, referring to FIG. 1, when a production photo resist dispensing step is about to occur, the main controller 6 directs the nozzle positioning mechanism 3 to position the dispensing nozzle 2 over a semiconductor wafer 25 positioned on coater plate 28. The main controller 6 then actuates the valve 20 to receive input fluid from the photo resist flow line 22 and, via the pump controller 12, activates the photo resist pump 26 to send photo resist 29 from the photo resist source 24 through the photo resist flow line 22 through valve 20 to the nozzle tip 4 to be dispensed on to the wafer 25. When the dispensing nozzle 2 has completed a production photo resist dispensing operation, the main controller 6 signals the pump controller 12 to stop sending photo resist 29 and close the input 21 to valve 20. The main controller then activates the nozzle positioning mechanism 3 to rotate the dispensing nozzle 2 to the idle position 10 over a solvent drain 30. Because the invention is based on a different principle than the interaction of solvent vapors with photo resist, the solvent drain 30 does not require that a solvent feed line be connected to fill the solvent drain 30 as present in a conventional the solvent cup, although the invention may incorporate this feature to provide solvent vapors about the dispensing nozzle 2.

In the idle position 10, the nozzle tip 4 typically retains some photo resist 29 thereabout, as residual from the previous production dispensing operation. The dispensing nozzle 2 may remain in the idle position 10 with photo resist 29 in the dispensing nozzle 2 and nozzle tip 4 in preparation for a subsequent production photo resist dispense operation. After a predetermined amount of time in the idle position 10, with no further wafers in queue for the production photo resist dispense operation, the main controller 6 actuates the valve 20 to open the input port 23 to the solvent flow line 18. The main controller 6 also signals the pump controller 12 to activate the solvent pump 16 to send solvent 19 from a solvent source 14 through the solvent flow line 18 through the valve 20 to the nozzle tip 4 to flush residual photo resist 29 through the nozzle tip 4 and fill the dispensing nozzle 2 and nozzle tip 4 with solvent.

Solvent 19 remains in the dispensing nozzle 2 until the next production photo resist dispense operation is initiated, thus eliminating the need for a dummy dispense operation. When a subsequent group of wafers, referred to herein as a next production lot, become available for a production photo dispense operation, the main controller 6 signals the photo resist pump to fill the dispensing nozzle 2 with photo resist 29, thereby replacing the solvent 19 with photo resist 29.

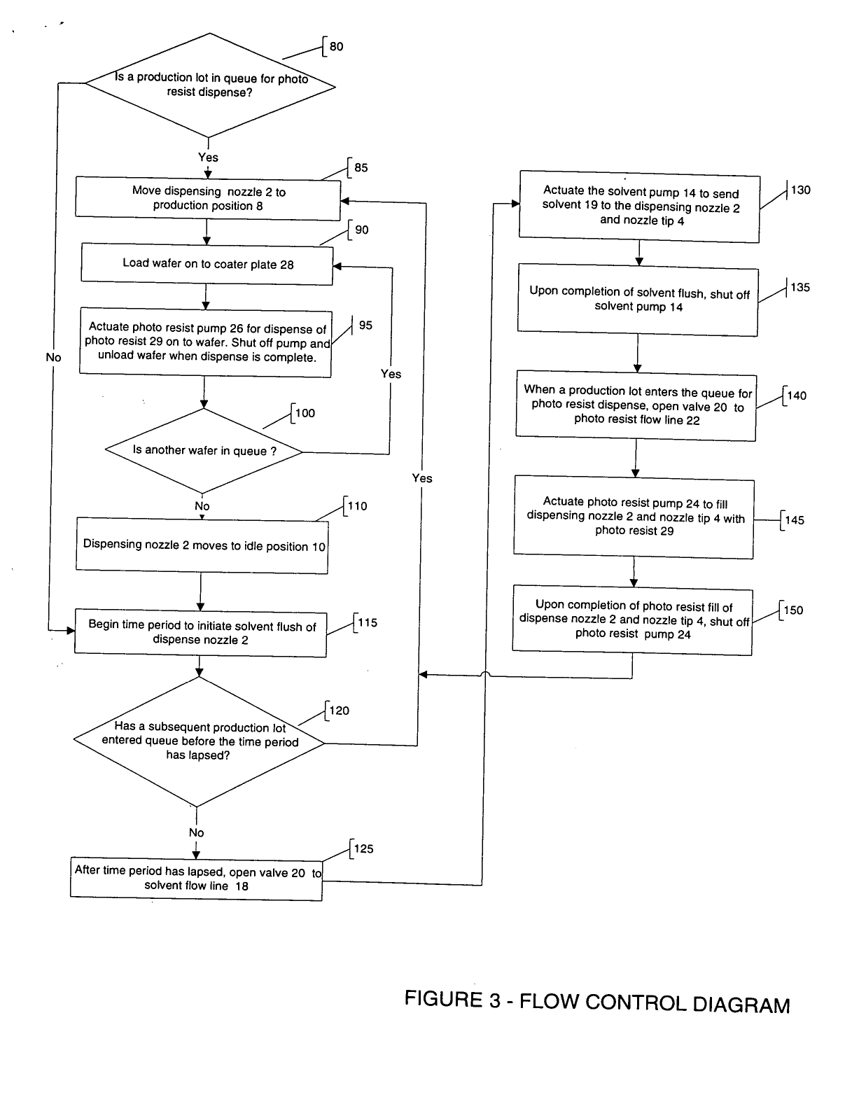

FIG. 3, a flow control diagram, provides a more detailed sequence of steps applicable to the embodiment of the invention shown in FIGS. 1 and 2. The sequence, beginning at step 80 assumes that the photo resist coater tool system 1 has the dispensing nozzle 2 in the idle position 10 with the valve 20 open to the photo resist flow line 22. The sequence of steps will typically be initiated and controlled by signals from the main controller 6, with secondary instructions sent to the pumps from the pump controller 12.

If a production lot has entered the queue for a production photo resist dispense, the system 1 begins a production dispense operation in which the main controller 6 sends a signal to move the dispensing nozzle 2 to the production position 8 (step 85) and a wafer is loaded onto the coater plate 28 (step 90). The main controller 6 then sends a signal to the pump controller 12 to actuate the photo resist pump 26 to dispense photo resist 29 onto the wafer 25. The photo resist pump 26 is subsequently shut off when the dispense operation for the wafer is complete (step 95).

If other wafers in the production lot remain in queue, the system 1 sequentially loads the remaining wafers on to the coater plate 28 (step 90) and continues with the production dispense operation (step 95). Otherwise, the dispensing nozzle 2 moves to the idle position 10 (step 110) and a time period is counted by the main controller 6 (step 115). If it is determined at step 80, that there are no further wafers in queue, the dispensing nozzle 2 remains in the idle position 10 and the time period is counted (step 115). A reasonable time period for the photo resist coater tool to remain in the idle position 10 before beginning the solvent flush is 30 minutes, but the period may range from less than 10 minutes to over 60 minutes. The length of the time period may depend on factors, such as the type of photo resist and solvent, viscosity of the photo resist, and the configuration of the dispensing nozzle 2 and nozzle tip, as well as, environmental conditions such as room temperature and humidity.

If wafers arrive in queue before the time period lapses (step 120), the dispensing nozzle 2 is moved into the production position 8 (step 85) to begin another production dispense operation. If no subsequent lot enters the queue before the time period ends (step 120), the main controller 6 sends a signal to open the valve 20 to the solvent flow line 18 (step 125) and the pump controller 12 actuates the solvent pump 14 to send solvent 19 to the dispensing nozzle 2 and nozzle tip 4 (step 130) to clear them of photo resist 29.

After flushing the dispensing nozzle 2 and nozzle tip 4 with solvent, the pump controller 12 shuts off the solvent pump 14 (step 135). The photo resist coater tool 1 remains in this state with the dispensing nozzle 2 in idle position 10 until a subsequent lot arrives in queue for the production dispense operation. When the subsequent lot arrives, the main controller 6 opens the valve 20 to the photo resist flow line 22 (step 140) and sends a signal to the pump controller 12 to actuate the photo resist pump 24 to fill the dispensing nozzle 2 and nozzle tip 4 with photo resist 29 (step 145). After the dispensing nozzle 2 and nozzle tip 4 are filled with photo resist, the pump controller 12 sends a signal to disable the photo resist pump 24 (step 150). The dispensing nozzle 2 then moves to a production position 8 to perform for another production dispense operation on the next wafer in queue (step 85).

It is to be understood that the above description of the invention is intended to be illustrative and not restrictive. Many additions and modifications will be apparent to those of skill in the art. The invention may be practiced in a number of industries pertaining to electronics manufacturing where a photo resist coating process is used. Accordingly, the scope of the invention is only limited by the claims which follow.

1. A method of manufacturing microelectronic devices, comprising:
providing a photo resist coater tool of the type having a coater plate and a nozzle connected to a fluid flow line, with the nozzle positionable over the coater plate;
providing a valve assembly positioned in the flow line to control flow between at least two fluid inputs and the nozzle,
positioning a wafer on the coater plate;
operating the valve assembly to dispense photo resist from the first of the fluid inputs and through the nozzle onto a wafer;
operating the valve assembly to stop the flow of photo resist, and
operating the valve assembly to send a solvent from a second of the fluid inputs through the flow line and nozzle to reduce coagulation of the photo resist in or about the nozzle.

2. The method of manufacturing microelectronic devices as in claim 1 wherein the step of sending solvent through the nozzle includes positioning the nozzle over a solvent drain.

3. The method of manufacturing microelectronic devices as in claim 1 wherein the step of sending solvent through the nozzle only occurs when the flow of photo resist though the nozzle has ceased for a pre-determined period of time.

4. The method of manufacturing microelectronic devices as in claim 3 wherein the pre-determined period of time is thirty minutes.

5. The method of manufacturing microelectronic devices as in claim 3 wherein the pre-determined period of time ranges from fewer than ten minutes to more than sixty minutes.

6. The method of manufacturing microelectronic devices as in claim 1 wherein the nozzle is permitted to again dispense photo resist prior to sending the solvent through the nozzle.

7. The method of manufacturing microelectronic devices as in claim 1 further including the step of positioning the nozzle over a solvent drain prior to the step of operating the valve assembly to send a solvent from a second of the fluid inputs through the flow line and nozzle.

8. The method of manufacturing microelectronic devices as in claim 1 wherein the valve assembly includes a three-way valve.

9. A method of manufacturing microelectronic devices as in claim 1 wherein the solvent is taken from the group consisting of
Propylene Glycol Monomethyl Ether Acetate (PGMEA),
Propylene Glycol Monomethyl Ether (PGME),
N-butyl Acetate,
Acetone,
Cyclohexnone,
Ethyl Lactate,
N-Methyl Pyrriolidone (NMP) (1-methyl, 2-Pyrrolidinone),
Tetrahydrofuran (THF),
and Methyl Amyl Keytone.

7. The method of manufacturing microelectronic devices as in claim 1 where in the step of sending solvent from a second fluid input includes flushing the solvent through the nozzle.

8. The method of manufacturing microelectronic devices as in claim 1 further including the step of operating the valve assembly to send photo resist through the nozzle in order to clear the nozzle of solvent prior to again dispensing photo resist.

9. The method of manufacturing microelectronic devices as in claim 1 wherein the steps of operating the valve assembly to stop the flow of photo resist and send solvent from a second of the fluid inputs is sequenced with a controller.

10. The method of manufacturing microelectronic devices as in claim 2 wherein the step of positioning the nozzle over a solvent drain is performed by rotating the nozzle about an axis to move from a production position over the coater plate to an idle position over the solvent drain.

11. A method of manufacturing microelectronic devices as in claim 1 wherein the step of operating the valve assembly to dispense photo resist from the first of the fluid inputs further includes activating a photo resist pump and the step of operating the valve assembly to send solvent from the second of the fluid inputs further includes activating a solvent pump.

12. A method of manufacturing microelectronic devices as in claim 11 wherein the photo resist pump and the solvent pump are activated by a pump controller.

13. A system for dispensing photo resist comprising:
a nozzle configured to alternately receive photo resist for delivery on to a plurality of wafers or liquid solvent to prevent coagulation of photo resist in the nozzle when the nozzle is idle;
a liquid source of photo resist;
a liquid source of solvent;
first and second flow lines providing fluid communication from the photo resist source and solvent source;
a valve assembly configured between the nozzle and at least the first and the second flow lines in order to select the movement of fluid from one or another of the flow lines, thereby enabling movement of solvent through the nozzle to flush photo resist therefrom.

14. A system for dispensing photo resist comprising:
a nozzle configured to alternately receive photo resist for delivery on to a plurality of wafers or liquid solvent to prevent coagulation of photo resist in the nozzle when the nozzle is idle;
a liquid source of photo resist;
a liquid source of solvent;
first and second flow lines providing fluid communication from the photo resist source and solvent source;
a valve assembly configured between the nozzle and at least the first and the second flow lines in order to select the movement of fluid from one or another of the flow lines, thereby enabling movement of solvent through the nozzle to flush photo resist therefrom;
a controller configured to operate the valve assembly to: selectively send photo resist to the nozzle for delivery to wafers and, after a pre-determined period of time, send solvent to the nozzle in order to clear photo resist from the nozzle.

15. The system for dispensing photo resist as in claim 14 wherein the pre-determined period of time ranges from less than 10 minutes to more than 60 minutes.

16. The system for dispensing photo resist as in claim 14 wherein the pre-determined period of time is 30 minutes.

17. The system for dispensing photo resist as in claim 14 further including a photo resist pump activated by signals from the controller to a pump controller to send photo resist from the photo resist source through the first flow line and a solvent pump activated by signals from the controller to the pump controller to send solvent from the solvent source through the second flow line.

18. The system for dispensing photo resist as in claim 13 wherein the valve assembly includes at least two input ports and an output port, the two input ports connected to each of the first and the second flow lines and the output port directing fluid toward the nozzle.

19. The system for dispensing photo resist as in claim 13 wherein the valve assembly is a three-way valve.

20. The system for dispensing photo resist as in claim 13 wherein the nozzle is connected to a nozzle positioning mechanism which permits the nozzle to move rotatably about an axis from a production position over a coater plate to an idle position over a solvent drain.
